(19) United States
(12) Patent Application Publication
(10) Pub. No.: US 2015/0129977 A1
(43) Pub. Date: May 14, 2015

(54) SEMICONDUCTOR ELECTROSTATIC DISCHARGE PROTECTION APPARATUS

(71) Applicant: UNITED MICROELECTRONICS CORPORATION, Hsinchu (TW)

(72) Inventors: Yu-Chun CHEN, Hsinchu County (TW); Chang-Tzu Wang, Taoyuan County (TW); Tien-Hao Tang, Hsinchu City (TW)

(73) Assignee: UNITED MICROELECTRONICS CORPORATION, Hsinchu (TW)

(21) Appl. No.: 14/074,727

(22) Filed: Nov. 8, 2013

(51) Int. Cl. H01L 27/02; H01L 27/088

(52) U.S. Cl. CPC H01L 27/0266; H01L 27/088
USPC 257/390

(57) ABSTRACT

A semiconductor electrostatic discharge (ESD) protection apparatus comprises at least one elementary transistor with a first conductivity type, a well region with a second conductivity type, a guard ring with the second conductivity type and a semiconductor interval region. The elementary transistor is formed in the well region. The guard ring surrounds the at least one elementary transistor. The semiconductor interval region is disposed between the elementary transistor and the guard ring in order to surrounds the elementary transistor, wherein the semiconductor interval region is an undoped region, a doped region with the first conductivity type or a doped region with the second conductivity type that has a doping concentration substantially less than that of the well region.

### BACKGROUND OF THE INVENTION

1. Field of Invention

The present invention relates to a semiconductor integrated circuit (IC) device, and more particularly, relates to a semiconductor electrostatic discharge (ESD) protection apparatus.

2. Description of Related Art

ESD is a transient process of high energy transformation from external to internal of an IC when the IC is floated. Several hundred or even several thousand volts are transferred during ESD stress. Such high voltage transfer will break down the gate oxide of an input stage and cause circuit error. As the thickness of gate oxide is scaled down constantly, it is more and more important to provide a protected circuit or device to protect the gate oxide and to discharge ESD stress.

One solution to the problem of ESD, is to provide a device for dispersing the ESD current into earth ground that is integrated into the IC. For example, a gate grounded n-type metal-oxide-semiconductor (GGNMOS) has been well known serves as an effective ESD protection device. The ESD protection provided by the GGNMOS is based on snapback mechanism. When the voltage reaches a level beyond the IC normal operation due to ESD zapping, the snapback mechanism enables the GGNMOS to conduct a high level ESD current between its drain and source and subsequently directs the ESD current into the earth ground. As a result, the IC can be protected from being broken down by the ESD stress.

However, there are still problems to the conventional GGNMOS. While the ESD zapping occurs, secondary snapback may be triggered easily due to base push-out effect of a parasitic bipolar junction transistor parasitized among the elementary transistors of the conventional GGNMOS. As a result, the conventional GGNMOS may be easily broken down, and thus to the point of permanently failure caused by an intolerable leakage current passing through the emitter and the grounded base of the parasitic bipolar junction transistor that is subsequently conducted into earth ground.

Therefore, how to prevent the current leaking from the parasitic bipolar junction transistor of the GGNMOS is still a challenge to the art of ESD protection.

### SUMMARY OF THE INVENTION

According to one aspect of the present invention, a semiconductor ESD protection apparatus is provided, wherein the semiconductor ESD protection apparatus comprises a first elementary transistor with a first conductivity type, a well region with a second conductivity type, a guard ring with the second conductivity type and a semiconductor interval region. The first elementary transistor is formed in the well region. The guard ring surrounds the first elementary transistor. The semiconductor interval region is disposed between the first elementary transistor and the guard ring in order to surround the first elementary transistor, wherein the semiconductor interval region is an undoped region, a doped region with the first conductivity type or a doped region with the second conductivity type that has a doping concentration substantially less than that of the well region.

In one embodiment of the present invention, the semiconductor ESD protection apparatus further comprises a shallow trench isolation (STI) disposed between the first elementary transistor and the guard ring, wherein the semiconductor interval region is disposed beneath the STI.

In one embodiment of the present invention, the semiconductor ESD protection apparatus further comprises a STI disposed between the first elementary transistor and the guard ring, wherein the semiconductor interval region is disposed between the guard ring and the STI.

In one embodiment of the present invention, the first conductivity type is n-type conductivity and the second conductivity type is p-type conductivity. In one embodiment of the present invention, the first conductivity type is p-type conductivity and the second conductivity type is n-type conductivity.

In one embodiment of the present invention, the first elementary transistor comprises a gate, a source, a drain and a heavy doped region with the second conductivity type. The gate is formed on the well region; the source is formed in the well region and adjacent to the gate. The drain is formed in the well region and adjacent to the gat. The heavy doped region is disposed within the well region and beneath the drain, as well as has a doping concentration substantially greater than that of the well region.

In one embodiment of the present invention, the semiconductor ESD protection apparatus further comprises a substrate contact region disposed adjacent to the well region and the guard ring, wherein the substrate contact region is electrically coupled to a ground reference voltage with the source and the guard ring, and the drain is electrically connected to an input/output (I/O) pad protected by the semiconductor ESD protection apparatus.

In one embodiment of the present invention, the semiconductor ESD protection apparatus further comprises a second elementary transistor and a third elementary both having the first conductivity type and formed in the well region, wherein the first elementary transistor, the second elementary transistor and the third elementary transistor have an common drain arranged at each side of the first elementary transistor, the second elementary transistor and the third elementary transistor departing from the guard ring.

In one embodiment of the present invention, the semiconductor ESD protection apparatus further comprises a second elementary transistor and a third elementary transistor both having the first conductivity type as well as a well pick-up region all formed in the well region, wherein the first elementary transistor, the second elementary transistor and the third elementary transistor have an annular common source arranged at each side of the first elementary transistor, the second elementary transistor and the third elementary transistor departing from the guard ring and surrounding the well pick-up region.

According to another aspect of the present invention, a semiconductor ESD protection apparatus is to provide, wherein the semiconductor ESD protection apparatus comprises a plurality of elementary transistors with a first conductivity type, a first guard ring with a second conductivity type and a well pick-up region, wherein the first guard ring surrounds the plurality of elementary transistors and the plurality of elementary transistors surround the well pick-up region.

In one embodiment of the present invention, the semiconductor ESD protection apparatus further comprises a second guard ring with the first conductivity type disposed between the first guard ring and the plurality of elementary transistors in order to surround the plurality of elementary transistors.

In one embodiment of the present invention, each of the plurality of elementary transistors comprises a gate, a source, a drain. The gate is disposed on a well region with the second conductivity type. The source is disposed in the well region and adjacent to one side of the gate near to the well pick-up region. The drain is disposed in the well region and adjacent to one side of the gate departing from the well pick-up region.

In one embodiment of the present invention, the well pick-up region is electrically coupled to a ground reference voltage with the source and the first guard ring, and the drain is electrically connected to an I/O pad protected by the semiconductor ESD protection apparatus.

In one embodiment of the present invention, each of the elementary transistors further comprises a heavy doped region disposed with in the well region and beneath the drain as well as having a doping concentration substantially greater than that of the well region.

According to aforementioned embodiments of the present invention, a semiconductor ESD protection apparatus is provided. In one embodiment of the present invention, the semiconductor ESD protection apparatus comprises an elementary transistor with a first conductivity type formed in a substrate, a guard ring with a second conductivity type surrounding the elementary transistor and a semiconductor interval region disposed between the guard ring and the elementary transistor, wherein the semiconductor interval region is an undoped region, a doped region with the first conductivity type or a doped region with the second conductivity type that has a doping concentration substantially less than that of the well region. By the way of disposing the semiconductor interval region between the guard ring and the elementary transistor, the distance of measuring from a drain of the elementary transistor to the grounded guard ring can be enlarged, and thus the resistance between the emitter and the grounded base of the bipolar junction transistor parasitized among the elementary transistor and the substrate of the semiconductor ESD protection apparatus can be increased. As a result, leakage current passing through the drain and the grounded substrate can be reduced, and ESD tolerance of the semiconductor ESD protection apparatus can be further enhanced.

In another embodiment of the present invention, a semiconductor ESD protection apparatus comprising a plurality of elementary transistors with a first conductivity type, a guard ring with a second conductivity type and a well pick-up region is provided. Wherein the guard ring surrounds the plurality of elementary transistors, these elementary transistors surround the well pick-up region. Similarly the distance between each drain of these elementary transistors and the well pick-up region can be enlarged by the particular arrangement of the plurality of elementary transistors, the guard ring and the well pick-up region, and thus the resistance between the emitter and the grounded base of the bipolar junction transistor parasitized among the elementary transistors and the substrate of the semiconductor ESD protection apparatus can be increased. As a result, leakage current passing through the drain and the grounded well pick-up region can be reduced, and ESD tolerance of the semiconductor ESD protection apparatus can be further enhanced.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a plan view illustrating a semiconductor ESD protection apparatus in accordance with one embodiment of the present invention.

FIG. 1B is a cross sectional view of the semiconductor ESD protection apparatus illustrated along the section line 51 shown in FIG. 1A;

FIG. 2A is a plan view illustrating a semiconductor ESD protection apparatus in accordance with an another embodiment of the present invention;

FIG. 2B is a cross sectional view of the semiconductor ESD protection apparatus illustrated along the section line S2 shown in FIG. 2A;

FIG. 3A is a plan view illustrating a semiconductor ESD protection apparatus in accordance with a yet another embodiment of the present invention;

FIG. 3B is a cross sectional view of the semiconductor ESD protection apparatus illustrated along the section line S3 shown in FIG. 3A;

FIG. 4A is a plan view illustrating a semiconductor ESD protection apparatus in accordance with a yet another embodiment of the present invention;

FIG. 4B is a cross sectional view of the semiconductor ESD protection apparatus illustrated along the section line S4 shown in FIG. 4A;

FIG. 5A is a plan view illustrating a semiconductor ESD protection apparatus in accordance with a yet another embodiment of the present invention; and

FIG. 5B is a cross sectional view of the semiconductor ESD protection apparatus illustrated along the section line S5 shown in FIG. 5A.

### DESCRIPTION OF EMBODIMENTS

An improved semiconductor ESD protection apparatus is provided by the present invention to prevent leakage current from passing through the drain and electrically coupled to a ground reference voltage by the substrate, so as to enhance ESD tolerance of the semiconductor ESD protection apparatus from being permanent failure. In order to make the aforementioned and other objects, features and advantages of the present invention comprehensible, detail descriptions of several embodiments accompanied with figures eligible to exemplify the features of making and using the present invention are described in detail below. However, it must be appreciated that the following embodiments are just exemplary, but not be used to limit the scope of the present invention. Wherever possible, the same reference numbers are used in the drawings and the description to refer to the same or like parts.

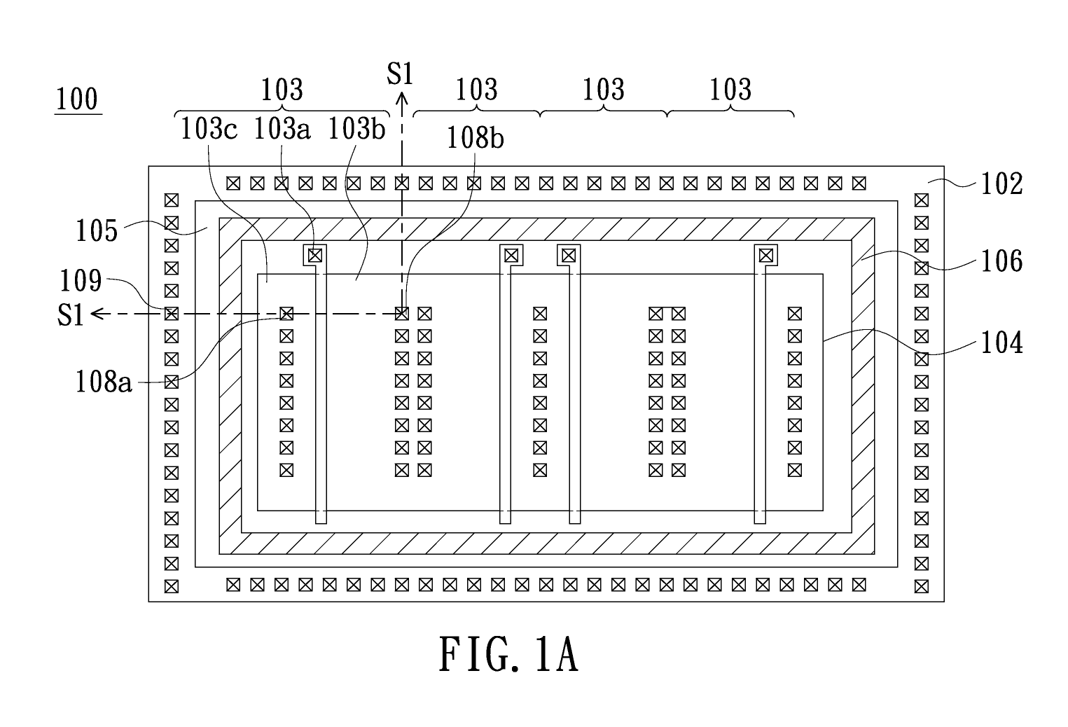

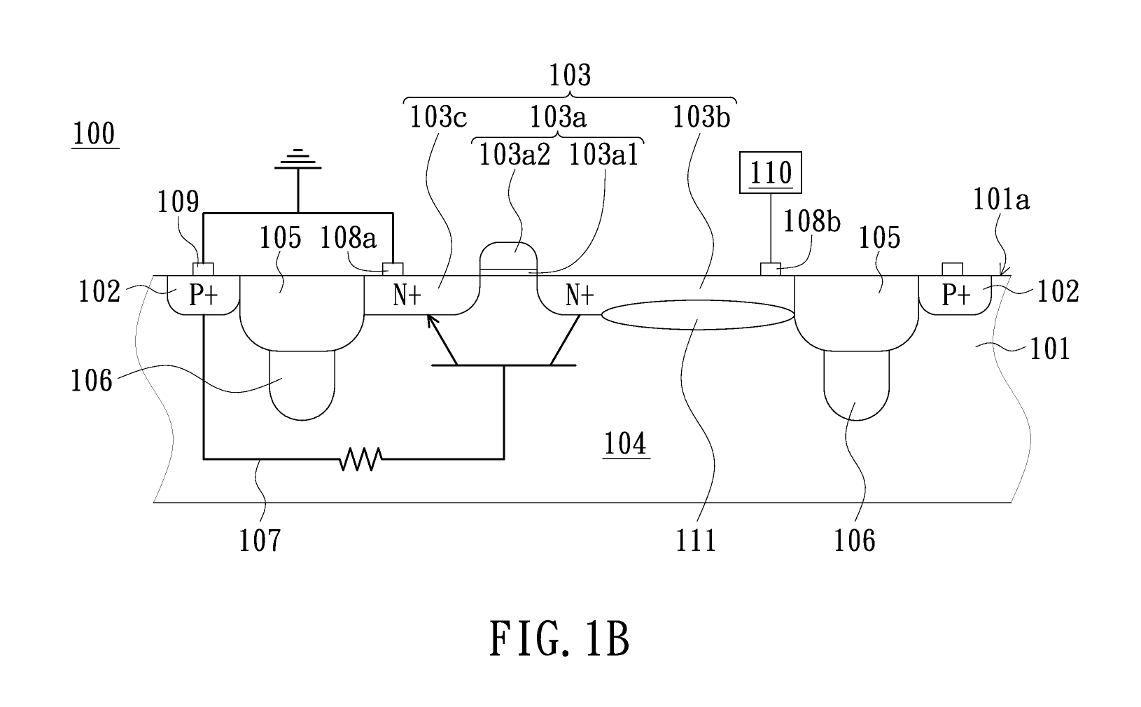

FIG. 1A is a plan view illustrating a semiconductor ESD protection apparatus 100 in accordance with one embodiment of the present invention. FIG. 1B is a cross sectional view of the semiconductor ESD protection apparatus 100 illustrated along a section line S1 shown in FIG. 1A. As shown in FIG. 1A, the semiconductor ESD protection apparatus 100 comprises at least one elementary MOS transistor 103 with a first conductivity type formed in a substrate 101 and surrounded by a guard ring 102 with a second conductivity type.

For purpose of increasing the tolerance for ESD current, the semiconductor ESD protection apparatus 100 may comprise a plurality of elementary MOS transistors 103. In addition, the plurality of elementary MOS transistors 103 may be designed as a multi-finger structure and to conserve the layout space. Thus, in some embodiments of the present invention, the semiconductor ESD protection apparatus 100 may be designed in a device configuration of having a plurality of finger elementary MOS transistors 103 surrounded by the guard ring 102 (as shown in FIG. 1A).

In one embodiment of the present invention, the first conductivity type is n-type conductivity and the second conductivity type is p-type conductivity. For example, in the present embodiment, each of the plurality of elementary MOS transistors 103 has a gate 103a, a drain 103b and a source 103c, wherein the gate 103a comprises a gate dielectric layer 103a1 disposed on a p-well 104 and a gate electrode 103a2 stacked on the gate dielectric layer 103a1; the drain 103b is a n-type doping region (shown as N+) extending downwards into the p-well 104 from a surface 101a of the substrate 101, and is disposed adjacent to one side of the gate 103a; and the source 103c is also a n-type doping region (shown as N+) extending downwards into the p-well 104 from the surface 101a of the substrate 101, and is disposed adjacent to another side of the gate 103a. The guard ring 102 is a p-type doping region (shown as P+) extending downwards into the p-well 104 from the surface 101a of the substrate 101, and is surrounding the plurality of n-type elementary MOS transistors 103.

However it should be appreciated that, in some other embodiments of the present invention, the first conductivity type is p-type conductivity and the second conductivity type is n-type conductivity. In other words, the first conductivity type and the second conductivity type described in the specific embodiments of the present invention are not limited thereto. The conductivity types of those regions described therein will be correspondingly altered according to the selections in their conductivity types of the elementary MOS transistor 103 and the guard ring 102.

The semiconductor ESD protection apparatus 100 further comprises a shallow trench isolation (STI) 105 and a semiconductor interval region 106, both of which are disposed between the guard ring 102 and the elementary MOS transistors 103 to form a ring-like structure surrounding the elementary MOS transistors 103. In some embodiments of the present invention, the STI 105 is an isolation structure made of dielectric material extending from the surface 101a of the substrate 101 downwards into the p-well 104, and the semiconductor interval region 106 is disposed beneath the STI 105. However, in some other embodiments, the semiconductor interval region 106 may be disposed between the STI 105 and the guard ring 102. In the present embodiment, the semiconductor interval region 106 is an n-type doping region formed in the substrate 101 and extending downwards from the bottom edge of the STI 105 into the p-well 104; and both of the STI 105 and the semiconductor interval region 106 surround the elementary MOS transistors 103.

In some embodiments of the present invention, the gate 103a and the source 103c of each elementary MOS transistor 103 as well as the guard ring 102 are electrically coupled to a ground reference voltage by the wires that are electrically connected to a plurality of conductive contacts 108a and 109, respectively; and the drain 103b is electrically connected to an I/O pad 110 through a conductive contact 108b, so as to provide ESD protection to the I/O pad 110. Since each of the elementary MOS transistors 103 is connected to the guard ring 102 through a substrate contact region 107, including a portion of the p-type substrate 101 disposed adjacent to the p-well 104 and the guard ring 102, thus a parasitic bipolar junction transistor is formed between the drain 103b, the source 103c and the guard ring 102.

Because the distance measuring from the guard ring 102 to the elementary MOS transistors 103 is enlarged by having the STI 105 and the semiconductor interval region 106 being disposed therebetween. The substrate contact region 107 can be broadened, and the resistance between the emitter and the grounded base of the bipolar junction transistor parasitized among the elementary MOS transistors 103 and the substrate 101 of the semiconductor ESD protection apparatus 100 can be increased. As a result, leakage current passing through the drain 103b and subsequently electrically coupled to a ground reference voltage by the substrate contact region 107 can be reduced, and ESD tolerance of the semiconductor ESD protection apparatus 100 can be further enhanced.

Besides, for purpose of increasing the resistance between the emitter and the grounded base of the parasitic bipolar junction transistor, a p-type heavy-doped region 111 is optionally disposed within the p-well 104 and beneath the drain 103b, wherein the p-type heavy-doped region 111 has a doping concentration substantially greater than that of the p-well 104.

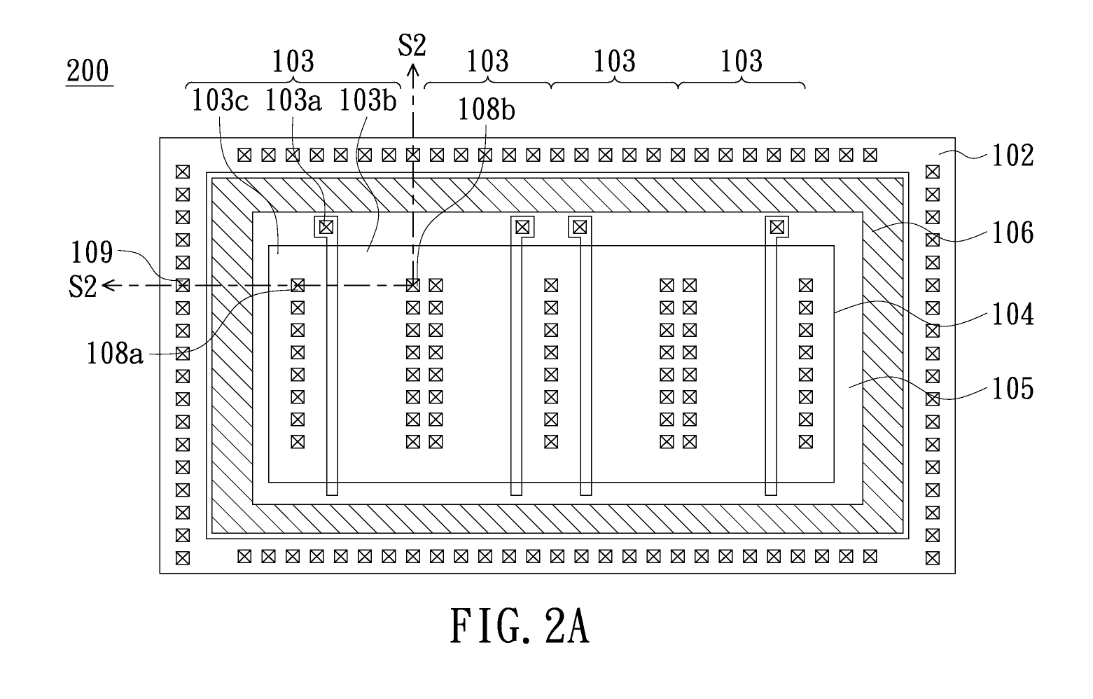

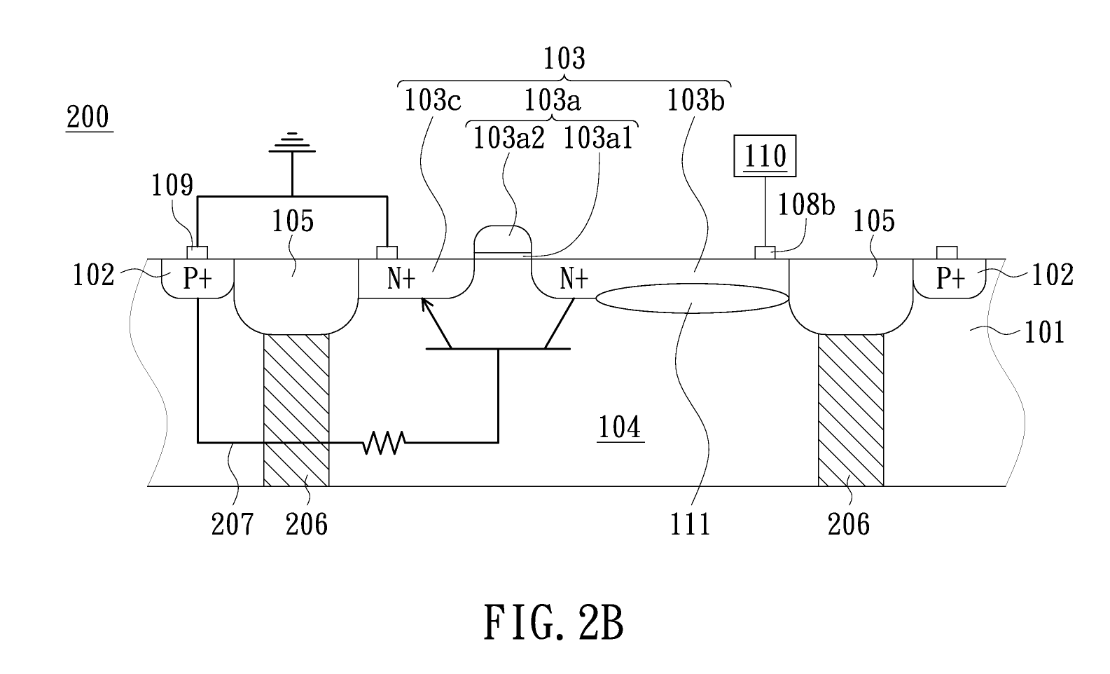

However, it is worthy to note that the arrangement and the material that is composing the semiconductor interval region 106 may be altered. For example, FIG. 2A is a plan view illustrating a semiconductor ESD protection apparatus 200 in accordance with an another embodiment of the present invention; and FIG. 2B is a cross sectional view of the semiconductor ESD protection apparatus 200 illustrated along the section line S2 shown in FIG. 2A. The physical structure of the semiconductor ESD protection apparatus 200 is similar to that of the semiconductor ESD protection apparatus 100 depicted in FIGS. 1A and 1B, except that the semiconductor interval region 206 is a p-type light doped region rather than an n-type doped region, and the p-type light doped region of the semiconductor interval region 206 has a doping concentration substantially less than that of the p-well 104.

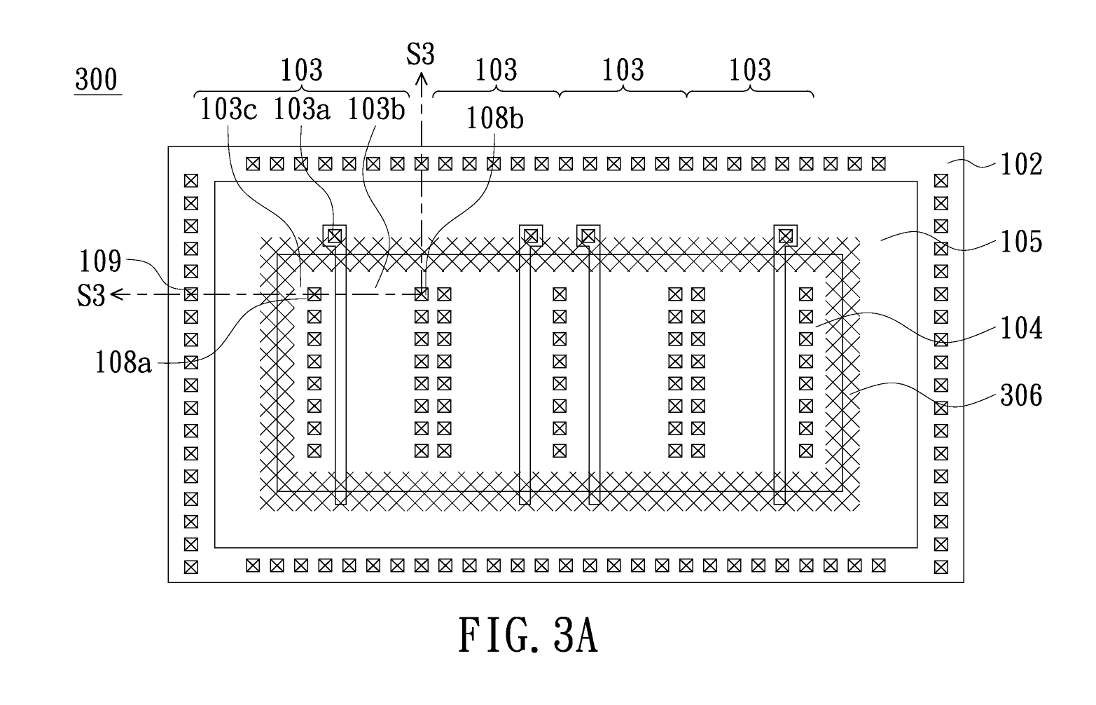

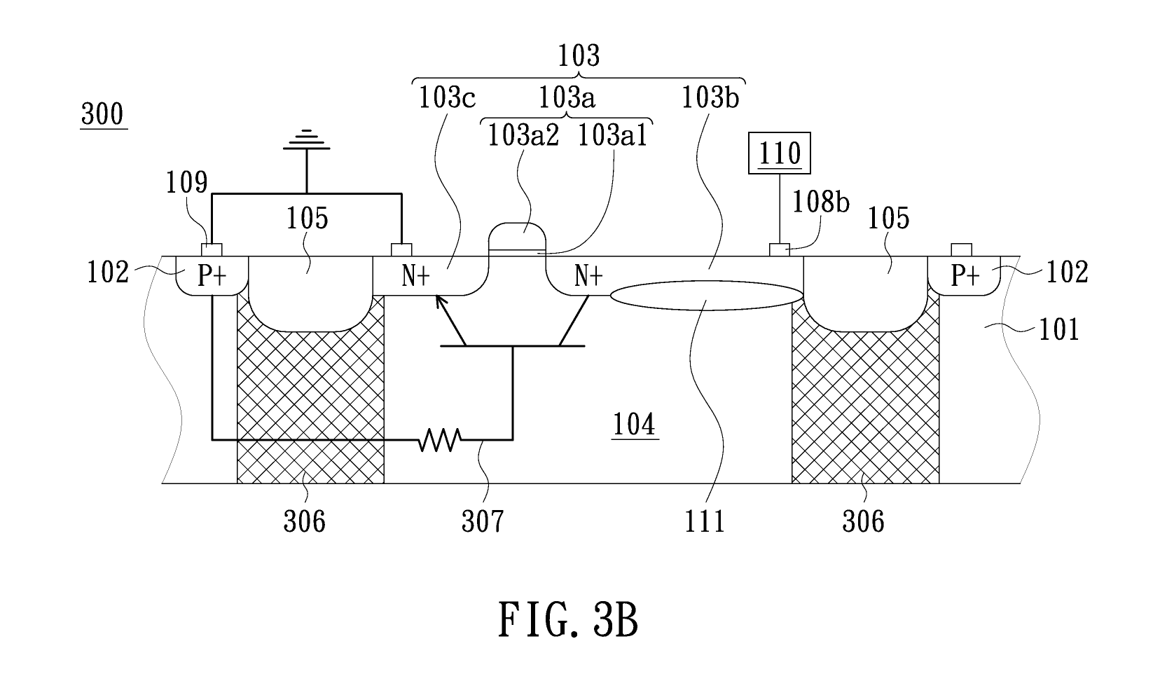

FIG. 3A is a plan view illustrating a semiconductor ESD protection apparatus 300 in accordance with a yet another embodiment of the present invention; and FIG. 3B is a cross sectional view of the semiconductor ESD protection apparatus 300 illustrated along the section line S3 shown in FIG. 3A. The physical structure of the semiconductor ESD protection apparatus 300 is similar to that of the semiconductor ESD protection apparatus 100 depicted in FIGS. 1A and 1B, except that the semiconductor interval region 306 is a non-doped region rather than an n-type doped region.

Because the adding of either the semiconductor interval region 206 composed by the nondoped region or the semiconductor interval region 306 composed by the p-type light doped region can physically enlarging the distance measuring from the guard ring 102 to the elementary MOS transistors 103. Thus the substrate contact regions 207 and 307 can be broadened and the resistance between the emitter and the grounded base of the bipolar junction transistor parasitized among the elementary MOS transistors 103 and the substrate 101 of the semiconductor ESD protection apparatus 200 and 300 can be increased. As a result, leakage current passing through the drain 103b and subsequently electrically coupled to a ground reference voltage by the substrate contact region 207 and 307 can be reduced, and ESD tolerance of the semiconductor ESD protection apparatus 200 and 300 can be further enhanced.

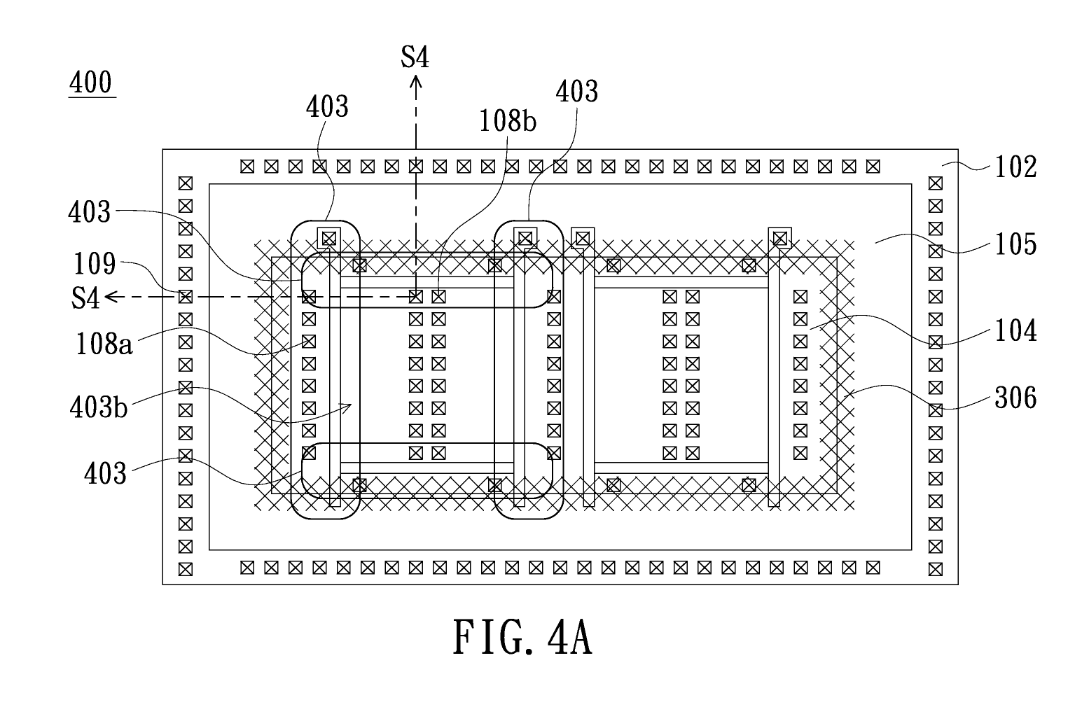

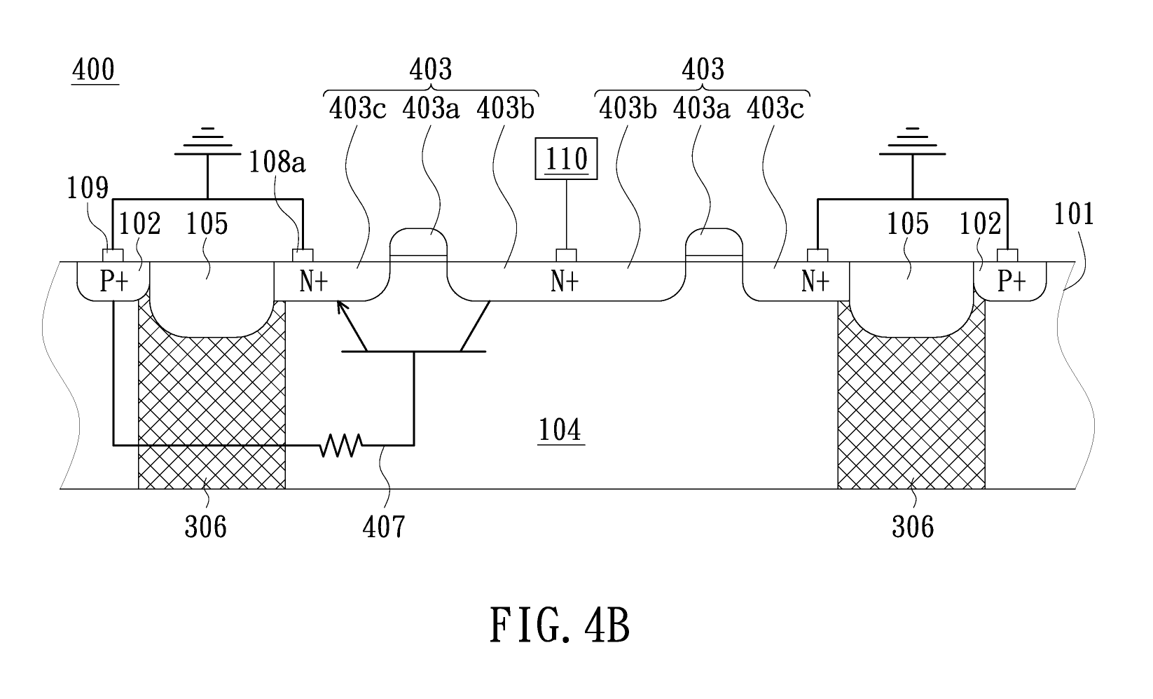

Otherwise, the function of increasing resistance between the emitter and the grounded base of the bipolar junction transistor parasitized among the elementary transistor and the substrate of the semiconductor ESD protection apparatus can be approached by applying different arrangements of the elementary transistors. FIG. 4A is a plan view illustrating a semiconductor ESD protection apparatus 400 in accordance with a yet another embodiment of the present invention; and FIG. 4B is a cross sectional view of the semiconductor ESD protection apparatus 400 illustrated along the section line S4 shown in FIG. 4A. The physical structure of the semiconductor ESD protection apparatus 400 is similar to that of the semiconductor ESD protection apparatus 300 depicted in FIGS. 3A and 3B, except for the arrangements of the elementary transistors 403 of the semiconductor ESD protection apparatus 400.

In the some embodiments of the present invention, the semiconductor ESD protection apparatus 400 at least comprises a plurality of elementary transistors 403 having a common drain 403b, and a plurality of gates 403a and a plurality of sources 403c of the elementary transistors 403 are arranged to form a ring-like structure surrounding the common drain 403b. In the present embodiment, four elementary transistors 403 are arranged as a rectangular ring-like structure by which the common drain 403b of these four elementary transistors 403 is surrounded (see FIG. 4A). By this approach, the common drain 403b can be arranged at a side of each elementary transistor 403 departing from the guard ring 102. The distance measuring from the guard ring 102 to the elementary transistors 403 can be thus enlarged, the substrate contact region 407 can be also broadened, and the resistance between the emitter and the grounded base of the bipolar junction transistor parasitized among the elementary transistors 403 and the substrate 101 of the semiconductor ESD protection apparatus 400 can be increased. As a result, leakage current passing through the common drain 403b and the subsequently electrically coupled to a ground reference voltage by the substrate contact region 407 can be reduced, and ESD tolerance of the semiconductor ESD protection apparatus 400 can be further enhanced.

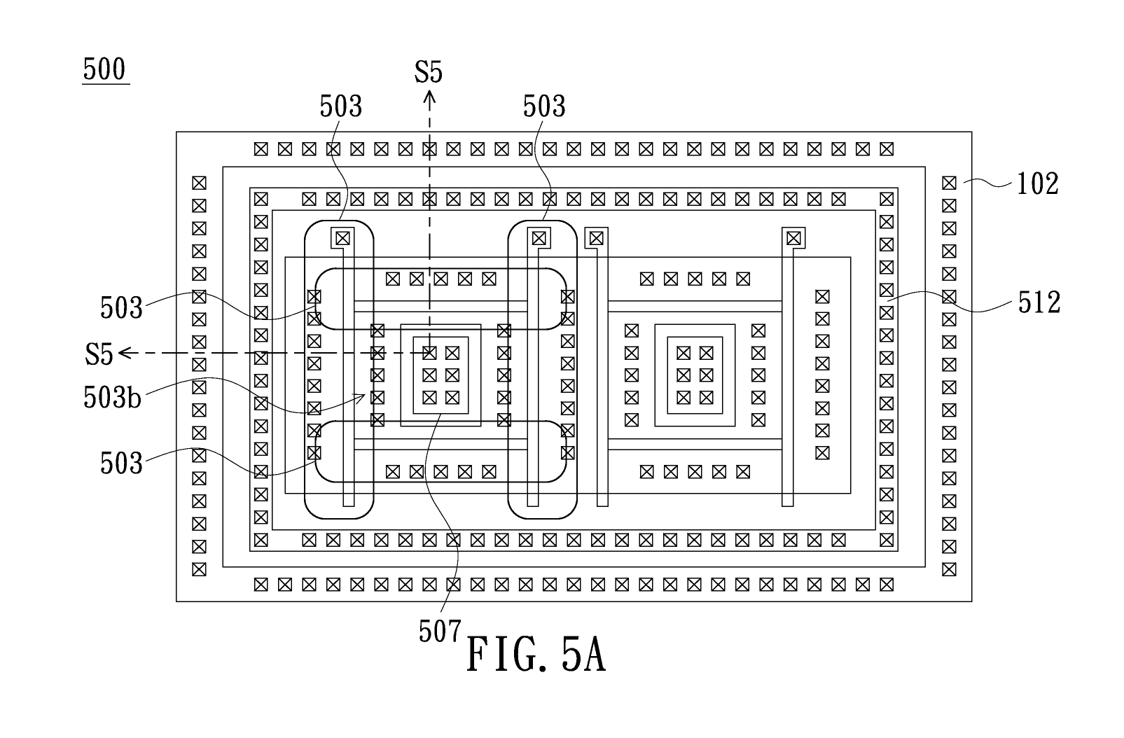

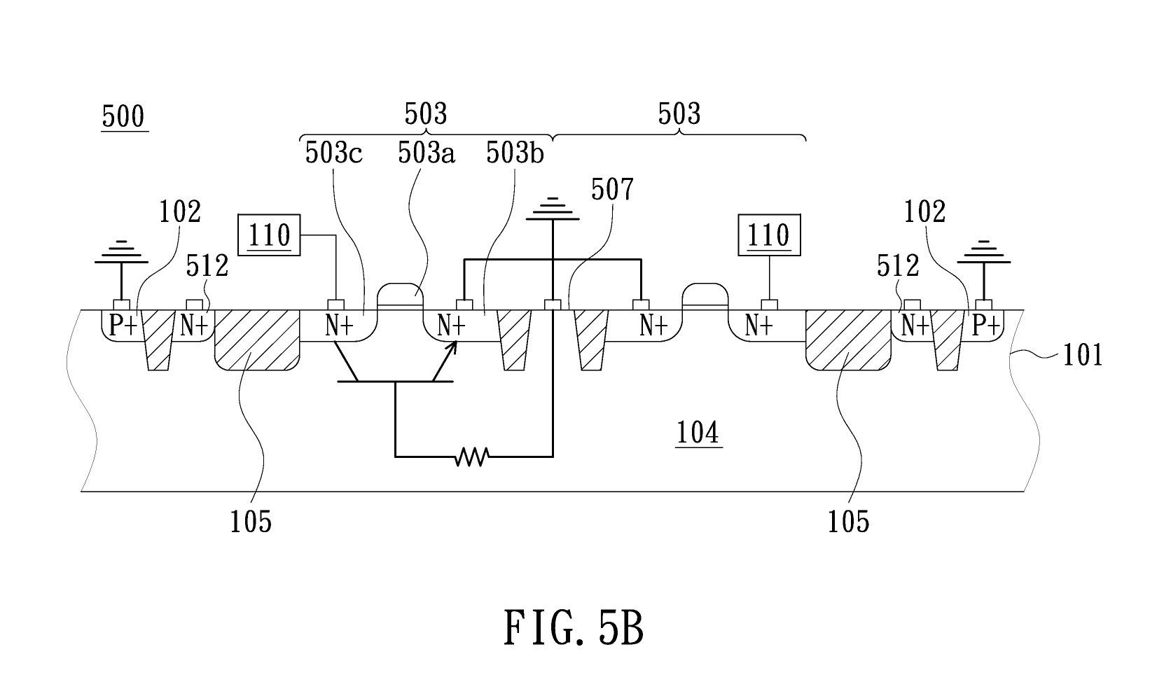

FIG. 5A is a plan view illustrating a semiconductor ESD protection apparatus 500 in accordance with a yet another embodiment of the present invention; and FIG. 5B is a cross sectional view of the semiconductor ESD protection apparatus 500 illustrated along the section line S5 shown in FIG. 5A. The physical structure of the semiconductor ESD protection apparatus 500 is similar to that of the semiconductor ESD protection apparatus 400 depicted in FIGS. 4A and 4B, except for the arrangements of the elementary transistors of the semiconductor ESD protection apparatus 500.

In some embodiments of the present invention, the semiconductor ESD protection apparatus 500 at least comprises a well pick-up region 507 and a plurality of elementary transistors 503, wherein the well pick-up region 507 is formed in the p-well region 104, one end of the well pick-up region 507 is grounded, and the plurality of elementary transistors 503 have an annular common source 503b. As explained in detail, in the present embodiment, four elementary transistors 503 are arranged as a rectangular ring-like structure, wherein the gates 503a and the drains 503c of the elementary transistors 503 are arranged to form a ring-like structure surrounding the annular common source 503b; and the annular common source 503b further surrounds the well pick-up region 507 (see FIG. 5A). By this approach, the drain 503c of each elementary transistor 503 can be arrange at a side departing from the well pick-up region 507, the distance measuring from the well pick-up region 507 to the drain 503c can be thus enlarged, and the resistance between the emitter and the grounded base of the bipolar junction transistor parasitized among the elementary transistors 503 and the substrate 101 of the semiconductor ESD protection apparatus 500 can be increased. As a result, leakage current passing through the drain 503c and the well pick-up region 507 can be reduced, and ESD tolerance of the semiconductor ESD protection apparatus 500 can be further enhanced.

Besides, for the purpose of preventing the semiconductor ESD protection apparatus 500 from being latched up, an n-type guard ring 512 may be provided between the guard ring 102 and the elementary transistors 503 to surround the elementary transistors 503. Besides, the n-type guard ring 512 may also serve as a semiconductor interval region to enlarge the distance measuring from the grounded guard ring 102 to the drain 503c of the elementary transistors 503, so as to increase the resistance between the emitter and the grounded base of the bipolar junction transistor parasitized among the elementary transistors 503 and the substrate 101 of the semiconductor ESD protection apparatus 500 and to enhance its ESD tolerance.

According to aforementioned embodiments of the present invention, a semiconductor ESD protection apparatus is provided. In one embodiment of the present invention, the semiconductor ESD protection apparatus comprises an elementary transistor with a first conductivity type formed in a substrate, a guard ring with a second conductivity type surrounding the elementary transistor and a semiconductor interval region disposed between the guard ring and the elementary transistor, wherein the semiconductor interval region is an undoped region, a doped region with the first conductivity type or a doped region with the second conductivity type that has a doping concentration substantially less than that of the well region. By the way of disposing the semiconductor interval region between the guard ring and the elementary transistor, the distance measuring from a drain of the elementary transistor to the grounded guard ring can be enlarged, and thus the resistance between the emitter and the grounded base of the bipolar junction transistor parasitized among the elementary transistor and the substrate of the semiconductor ESD protection apparatus can be increased. As a result, leakage current passing through the drain and the grounded substrate can be reduced, and ESD tolerance of the semiconductor ESD protection apparatus can be further enhanced.

In another embodiment of the present invention, a semiconductor ESD protection apparatus comprising a plurality of elementary transistors with a first conductivity type, a guard ring with a second conductivity type and a well pick-up region is provided. Wherein the guard ring surrounds the plurality of elementary transistors, these elementary transistors surround the well pick-up region. Similarly the distance between each drain of these elementary transistors and the well pick-up region can be enlarged by the particular arrangement of the plurality of elementary transistors, the guard ring and the well pick-up region, and thus the resistance between the emitter and the grounded base of the bipolar junction transistor parasitized among the elementary transistors and the substrate of the semiconductor ESD protection apparatus can be increased. As a result, leakage current passing through the drain and the grounded well pick-up region can be reduced, and ESD tolerance of the semiconductor ESD protection apparatus can be further enhanced.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

1. A semiconductor ESD protection apparatus comprising:
a first elementary transistor with a first conductivity type, formed in a well region with a second conductivity type;
a guard ring with the second conductivity type surrounding the first elementary transistor; and
a semiconductor interval region, disposed between the first elementary transistor and the guard ring, and surrounding the first elementary transistor;
wherein the semiconductor interval region is an undoped region, a doped region with the first conductivity type or a doped region with the second conductivity type that has a doping concentration substantially less than that of the well region.

2. The semiconductor ESD protection apparatus according to claim 1, further comprising a shallow trench isolation (STI) disposed between the first elementary transistor and the guard ring, wherein the semiconductor interval region is disposed beneath the STI.

3. The semiconductor ESD protection apparatus according to claim 1, further comprising a shallow trench isolation (STI) disposed between the first elementary transistor and the guard ring, wherein the semiconductor interval region is disposed between the guard ring and the STI.

4. The semiconductor ESD protection apparatus according to claim 1, wherein the first conductivity type is n-type conductivity and the second conductivity type is p-type conductivity.

5. The semiconductor ESD protection apparatus according to claim 1, wherein the first conductivity type is p-type conductivity and the second conductivity type is n-type conductivity.

6. The semiconductor ESD protection apparatus according to claim 1, wherein the first elementary transistor comprises:
a gate, formed on the well region;
a source, formed in the well region and adjacent to the gate;
a drain, formed in the well region and adjacent to the gate; and
a heavy-doped region with the second conductivity type, disposed within the well region and beneath the drain as well as having a doping concentration substantially greater than that of the well region.

7. The semiconductor ESD protection apparatus according to claim 6, further comprising a substrate contact region disposed adjacent to the well region and the guard ring; wherein the substrate contact region is electrically coupled to a ground reference voltage with the source and the guard ring, and the drain is electrically connected to an input/output (I/O) pad protected by the semiconductor ESD protection apparatus.

8. The semiconductor ESD protection apparatus according to claim 1, further comprising:
a second elementary transistor with the first conductivity type formed in the well region; and
a third elementary transistor with the first conductivity type formed in the well region, wherein the first elementary transistor, the second elementary transistor and the third elementary transistor have a common drain.

9. The semiconductor ESD protection apparatus according to claim 1, further comprising:
a substrate contact region formed in the well region;
a second elementary transistor with the first conductivity type formed in the well region; and
a third elementary transistor with the first conductivity type formed in the well region, wherein the first elementary transistor, the second elementary transistor and the third elementary transistor have an annular common source surrounding the substrate contact region.

10. A semiconductor ESD protection apparatus comprising:
a plurality of elementary transistors with a first conductivity type;
a first guard ring with the second conductivity type surrounding the plurality of elementary transistors; and
a well pick-up region, surrounded by the plurality of elementary transistors.

11. The semiconductor ESD protection apparatus according to claim 10, further comprising a second guard ring with the first conductivity type disposed between the first guard ring and the plurality of elementary transistors in order to surround the plurality of elementary transistors.

12. The semiconductor ESD protection apparatus according to claim 10, wherein each of the plurality of elementary transistors comprises:
a gate, disposed on a well region with the second conductivity type;
a source, disposed in the well region and adjacent to one side of the gate near to the well pick-up region;
a drain disposed in the well region and adjacent to one side of the gate departing from the well pick-up region.

13. The semiconductor ESD protection apparatus according to claim 12, wherein the well pick-up region is electrically coupled to a ground reference voltage with the source and the first guard ring, and the drain is electrically connected to an I/O pad protected by the semiconductor ESD protection apparatus.

14. The semiconductor ESD protection apparatus according to claim 12, wherein each of the elementary transistors further comprises a heavy-doped region disposed within the well region and beneath the drain as well as having a doping concentration substantially greater than that of the well region.
